(19) United States
(12) Patent Application Publication
(10) Pub. No.: US 2025/0239456 A1
(43) Pub. Date: Jul. 24, 2025

(54) CHEMICAL MECHANICAL POLISHING PROCESS AND CHEMICAL MECHANICAL POLISHING COMPOSITION

(71) Applicant: EBARA CORPORATION, Tokyo (JP)

(72) Inventors: Koichi MASUYA, Tokyo (JP); Chikako TAKATOH, Tokyo (JP); Ryota KOSHINO, Tokyo (JP)

(73) Assignee: EBARA CORPORATION, Tokyo (JP)

(21) Appl. No.: 19/026,507

(22) Filed: Jan. 17, 2025

(30) Foreign Application Priority Data
Jan. 22, 2024 (JP) 2024-007635

(51) Int. Cl. H01L 21/306; C09K 3/14; H01L 21/02

(52) U.S. Cl. CPC H01L 21/30625; C09K 3/1409; C09K 3/1463; H01L 21/02057

(57) ABSTRACT

A process of chemical mechanical polishing (CMP) is provided, the process including the step of subjecting a substrate to chemical mechanical polishing (CMP) using a chemical mechanical polishing composition including an abrasive grain that is hydroxyapatite (HAp), water, and a pH adjuster. Upon cleaning of substrate after CMP, residual HAp can be removed by bringing the substrate into contact with an acid.

### CROSS-REFERENCE TO RELATED APPLICATIONS

The present application claims priority to Japanese Patent Application No. 2024-007635, filed on Jan. 22, 2024. The entire disclosure of Japanese Patent Application No. 2024-007635, including the description, claims, drawings, and abstract, is hereby incorporated by reference in its entirety.

### BACKGROUND OF THE INVENTION

The present invention relates to a chemical mechanical polishing process and a polishing composition for use in the chemical mechanical polishing process.

Chemical mechanical polishing (CMP) is used to flatten surfaces of substrates for use in production of semiconductor elements. In CMP, surfaces of the substrates are polished using a suspension (slurry) containing an abrasive grain and a polishing aid. In CMP, a large amount of particles is generated due to polished debris and an abrasive grain in the slurry, and therefore cleaning processing is then performed to remove these substances. If cleaning processing is inappropriate, defects in the structure of the substrate occur, resulting in poor characteristics of semiconductor elements. Accordingly, it is required to surely remove such foreign substances.

As an abrasive grain for CMP, an abrasive grain made of silica particles (see JP 2023-148461 A) and an abrasive grain made of ceria (cerium oxide) particles (see JP 2023-98704 A) are generally used. Also, as a cleaning process after CMP, processes are known in which SC1 cleaning, SC2 cleaning, and the like are combined depending on the purpose (see JP 2023-73560 A). The SC1 cleaning is a method for using an alkaline cleaning solution in which ammonia solution and hydrogen peroxide solution are mixed at an arbitrary ratio to etch the surface of the substrate to strip off the attached particles, and further using electrostatic repulsion to remove the particles while inhibiting them from re-adhesion to the substrate. The SC2 cleaning is a method for using a cleaning solution in which hydrochloric acid and hydrogen peroxide solution are mixed at an arbitrary ratio to dissolve and remove trace metal impurities on the surface of the substrate. Also, in combination with such a cleaning solution, physical cleaning that physically sweeps out particles using cleaning members such as a roll brush and pencil brush, and non-contact physical cleaning such as ultrasonic cleaning are employed.

In recent years, a size of an abrasive grain used has become smaller due to demands for miniaturization in the semiconductor industry. Accompanying such demands, the size and number of foreign substances acceptable after substrate cleaning tend to be made stricter. This may arise cases where insufficient cleaning performance results from the use of the above-described conventional methods.

Hydroxyapatite (HAp) is a major constituent of teeth and bones of vertebrates such as humans, and has been widely used as medical equipment and dental materials. It has also been reported that HAp particles can be used as an example of an abrasive for polishing painted surfaces of automobiles and the like, taking advantage of its moderate hardness (see JP 2001-226665 A). However, there have been no reports of using the HAp as an abrasive for CMP.

### SUMMARY OF THE INVENTION

The present invention relates to a CMP process and an abrasive composition for the CMP process.

One aspect of the present invention is the CMP process, the process including the following steps:
providing a chemical mechanical polishing composition (CMP composition) containing
   an abrasive grain that is HAp,
   water, and
   a pH adjuster; and
   using the CMP composition to perform CMP on a substrate.

Another aspect of the present invention is the CMP process, further including cleaning the substrate after CMP,
wherein the cleaning includes bringing the substrate into contact with an acid to remove the residual HAp.

In further another aspect of the present invention, the acid is an aqueous solution of an organic acid.

In further another aspect of the present invention, the aqueous solution of the organic acid is an aqueous solution of citric acid.

In further another aspect of the present invention, the aqueous solution of the organic acid has a concentration of 0.1 to 10.0% by mass.

In further another aspect of the present invention, the substrate is brought into contact with the acid in an environment of 10 to 40° C.

In further another aspect of the present invention, following the cleaning, drying the substrate may be included.

In further another aspect of the present invention, the CMP composition has a pH of 6.0 to 14.0.

In further another aspect of the present invention, the HAp has an average particle size of 1 to 1,000 nm.

In further another aspect of the present invention, the pH adjuster is at least one selected from potassium hydroxide, calcium hydroxide, ammonia, or an arbitrary combination thereof.

In further another aspect of the present invention, the substrate is a semiconductor element.

In further another aspect of the present invention, the CMP composition has zeta potential of −5 mV or less.

In further another aspect of the present invention, the CMP composition further includes an additive, the additive being at least one selected from a dispersant, a surfactant, a pH stabilizer, a solvent other than water, or an arbitrary combination thereof.

In further another aspect of the present invention, the additive has a total concentration of 0.001 to 10.0% by mass based on the mass of the CMP composition. Alternatively, the CMP composition may be free of the additive.

### BRIEF DESCRIPTION OF DRAWINGS

FIG. 1 is a flow diagram illustrating one aspect of the CMP process of the present invention.

FIG. 2 is a flow diagram illustrating another aspect of the CMP process of the present invention.

FIG. 3 is a flow diagram illustrating yet another aspect of the CMP process of the present invention.

FIG. 4A is a scanning electron microscope image (1,000-time magnification) of a substrate after cleaning with ultrapure water in a cleaning test of Example.

FIG. 4B is a scanning electron microscope image (5,000-time magnification) of a substrate after cleaning with ultrapure water in a cleaning test of Example.

FIG. 5A is a scanning electron microscope image (1,000-time magnification) of a substrate after cleaning with an aqueous solution of citric acid in a cleaning test of Example.

FIG. 5B is a scanning electron microscope image (5,000-time magnification) of a substrate after cleaning with an aqueous solution of citric acid in a cleaning test of Example.

### DETAILED DESCRIPTION OF THE INVENTION

The present inventors have conducted diligent investigations on significant reduction of the amount of abrasive grains for CMP remaining on a substrate after cleaning. As a result, the present inventors came up with the idea of reducing the amount of abrasive grains remaining on a substrate after cleaning by dissolving the abrasive grains upon cleaning. However, silica and ceria, which have been used conventionally as abrasive grains for CMP, are difficult to be dissolved, thereby requiring a very strong acid such as hydrofluoric acid to dissolve the silica. Also, high temperature is required to dissolve the ceria in addition to sulfuric acid and hydrogen peroxide. As a result of further investigations on abrasive grains that can be more easily removed by way of dissolution, the present inventors have found that HAp can be dissolved at room temperature with an acid such as citric acid, which is relatively easy to handle. The present inventors have also found that when the HAp is used as an abrasive grain for CMP, the HAp can be easily dissolved and removed by cleaning with an acidic aqueous solution, as a result of which the amount of abrasive grains remaining on a substrate can be reduced.

In the present invention, HAp is used as an abrasive grain in the CMP composition. Accordingly, bringing a polished substrate into contact with an acid such as citric acid at room temperature, enables HAp to be dissolved to facilitate removal of abrasive grains. The conventional physical cleaning using a brush or the like in combination with a cleaning solution may have made it difficult to completely remove an abrasive grain with a small grain size. Contrary thereto, the abrasive grain using the HAp in the present invention is easily dissolved in acid, so that even the abrasive grain with a small grain size can be more reliably removed by cleaning with an acid.

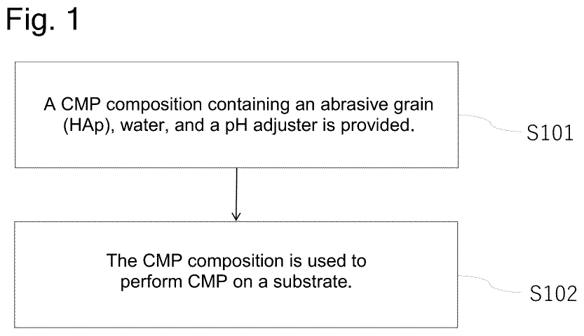

FIG. 1 shows one aspect of the CMP process of the present invention. In the CMP process of the present invention, a CMP composition containing at least an abrasive grain that is HAp, water, and a pH adjuster is provided (S101). Next, the CMP composition is used to perform CMP on a substrate (S102).

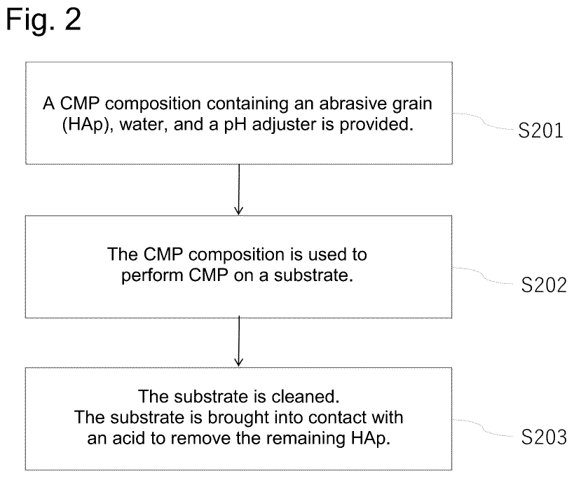

FIG. 2 shows another aspect of the CMP process of the present invention. In the process shown in FIG. 2, cleaning a substrate is further included in the process shown in FIG. 1 (S203). In cleaning the substrate, the substrate is brought into contact with an acid to remove the HAp remaining on the substrate.

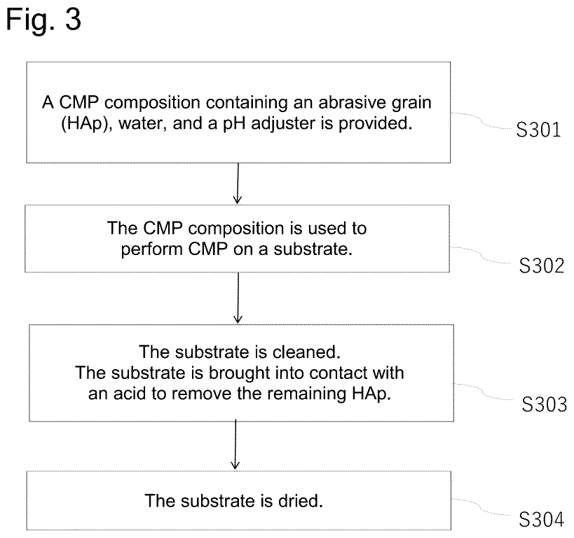

FIG. 3 shows yet another aspect of the CMP process of the present invention. In the process shown in FIG. 3, drying a substrate after cleaning is further included in the process shown in FIG. 2 (S304).

The CMP composition used in the CMP process of the present invention contains an abrasive grain, water, and a pH adjuster, and the abrasive grain is the HAp. The CMP is a process for polishing a surface of a substrate, taking advantages of a surface chemical action of the abrasive grain and/or a chemical action of the component in the CMP composition, as well as a mechanical action caused by contact between a slurry and the substrate.

The HAp used as the abrasive grain in the CMP process of the present invention is a compound having a general formula of Ca₁₀(PO₄)₆(OH)₂, also called as calcium hydroxide phosphate. In the present invention, the HAp may be derived from a natural product or may be a synthetic HAp. From the viewpoint of obtaining a homogeneous HAp, the synthetic HAp is preferable. The method for synthesizing the HAp is not particularly limited, and it may be obtained by any known method such as a dry method, a wet method, a hydrothermal method, or a spray pyrolysis method. Examples of starting raw materials to be used for HAp synthesis include, but are not limited to, calcium carbonate, calcium hydroxide, calcium oxide, calcium nitrate, calcium salts of organic acid, calcium hydrogen phosphate, phosphoric acid, ammonium hydrogen phosphate.

The HAp is used as the abrasive grain in the CMP process of the present invention, and is present as a particle in a dispersion medium of a slurry. In the present invention, when the HAp used as the abrasive grain is removed by cleaning after polishing, the HAp can be removed by being dissolved in an acid, so that the HAp can be made into, but is not limited to, an abrasive grain with a small size, which has been difficult to remove by conventional cleaning processes. The abrasive grain with a small size has advantages of being less likely to scratch a surface of a substrate and of being capable of controlling a surface roughness of the substrate more precisely. Therefore, from the viewpoint of its polishing performance and facilitation of being removed in cleaning after polishing, the HAp has an average particle size of preferably 1,000 nm or less, more preferably 500 nm or less, more preferably 300 nm or less, and more preferably 150 nm or less. The lower limit of the average particle size is not particularly limited, but may be 1 nm or more, for example, 5 nm or more, or 10 nm or more. As the average particle size of HAp used herein, an average particle size obtained by using a cumulant method based on the dynamic light scattering method of JIS Z 8828 is used.

A concentration of HAp (solid content) in the CMP composition is not particularly limited as long as it is an amount that allows the abrasive grain to flow sufficiently in the composition, but from the viewpoint of polishing performance, it is preferably approximately 1.0 to 35.0% by mass, more preferably 3.0 to 30.0% by mass, still more preferably 7.0 to 25.0% by mass, and even still more preferably 10.0 to 20.0% by mass.

The CMP composition used in the process of the present invention contains water as a dispersion medium for abrasive grains. The CMP composition also contains a pH adjuster. Using the pH adjuster, a pH of the composition is adjusted to within a predetermined range. Examples of the pH adjusters include, but are not limited to, inorganic bases such as potassium hydroxide, calcium hydroxide, ammonia, and sodium hydroxide, and organic bases such as tetramethylammonium hydroxide, triethylamine, triethanolamine, monoethanolamine, imidazole, and 2-methylimidazole. One of these may be used, or two or more thereof may be combined for use. Among these, potassium hydroxide or ammonia is preferred.

The CMP composition has a pH of preferably approximately 6.0 to 14.0, more preferably 6.0 to 12.0, and still more preferably 6.5 to 11.0, from the viewpoints of storage stability, a polishing rate, and removal performance upon cleaning. The pH of the composition can be measured using a commercially available pH meter at a liquid temperature of 25° C.

The CMP composition may further contain an additive in addition to the abrasive grain, water, and pH adjuster for the purpose of improving dispersibility of abrasive grains, enhancing storage stability, and the like. Examples of such additives include, for example, a dispersant, a surfactant, a pH stabilizer, and a solvent other than water. The CMP composition may contain one of these, or may contain two or more thereof. Also, the CMP composition may be free of these additives.

Examples of the dispersants include, but are not limited to, sodium tripolyphosphate, sodium polyacrylate, ammonium polyacrylate, sodium silicate, sodium pyrophosphate, sodium hexametaphosphate, sodium polyaluminate, sodium tetraborate, sodium triphosphate, sodium polystyrenesulfonate, or an arbitrary combination thereof.

Examples of the surfactants include, but are not limited to, an alkyl sulfuric acid ester salt, an alkyl ether sulfuric acid ester salt, a higher alcohol sulfuric acid ester salt, an alkyl phosphoric acid ester salt, an α-olefinsulfonate, an alkylsulfonate, styrenesulfonate, an alkylnaphthalenesulfonate, a taurine-based surfactant, a sarcosinate-based surfactant, an isethionate-based surfactant, a N-acyl acidic amino acid-based surfactant, a higher fatty acid salt, an acylated polypeptide, or an arbitrary combination thereof.

Examples of the pH stabilizers include various buffer solutions. Also, examples of the solvents other than water include, but are not limited to, solvents such as ethanol and acetone, which can be used arbitrarily in order to increase the solubility of various additives. When the additive other than the abrasive grain, water, and pH adjuster is used in the CMP composition, the total concentration of the additives may be appropriately set depending on a purpose and is not particularly limited, but it may be, for example, approximately 0.001 to 10.0% by mass or approximately 0.005 to 5.0% by mass based on the mass of the CMP composition. The CMP composition may also be free of such additives.

From the viewpoint of dispersion stability of the abrasive grains, the CMP composition has zeta potential of preferably −5 mV or less, more preferably −10 mV or less, and still more preferably −20 mV or less. The zeta potential is an index of the state of charge on a particle surface in a slurry. The repulsive force between particles becomes stronger as the value of the zeta potential is away from zero, and the particles generally become less likely to aggregate, thereby improving the dispersion stability upon storage of the slurry. The zeta potential can be measured using a commercially available zeta potential meter that uses an electrophoretic method.

The CMP composition can be prepared by dispersing HAp used as an abrasive grain in water and adding a pH adjuster and a variety of additives, if necessary. The order of mixing the components upon preparation is not particularly limited. Also, an apparatus used upon dispersion is not particularly limited.

In the process of the present invention, providing CMP composition includes the preparation of CMP composition as described above. In another aspect, providing the CMP composition includes adding a pH adjuster to a commercially available HAp water slurry. In yet another aspect, providing the CMP composition may involve purchasing a commercially available slurry containing HAp and a pH adjuster, and optionally modifying concentrations of the HAp and/or the pH adjuster.

The CMP composition is a composition for polishing a substrate using the CMP process, and is generally in a form of a slurry. The substrate is not particularly limited as long as it is an object to which the CMP process can be applied. Examples thereof include a substrate having silicon oxide applied to a surface of the substrate, and the like. In addition to silicon oxide, a substrate having glass, silicon nitride, polysilicon, aluminum, copper, titanium, titanium nitride, tungsten, tantalum, or tantalum nitride on its surface may also be used as an object to be polished. The substrate may also be, but is not limited to, semiconductor elements such as a diode, a transistor, a varistor, a thyristor, a memory element, a logical circuit element, an integrated circuit element, a photoelectric conversion element, and a solar cell.

The CMP process using the CMP composition of the present invention is not particularly limited. Upon CMP, a CMP apparatus may be used. The CMP apparatus generally includes a polishing table that supports a polishing pad having a polishing surface, and a substrate holding member for holding the substrate. The substrate is pressed against the polishing surface with a predetermined pressure by the substrate holding member, and the polishing table and the substrate holding member are moved relative to each other while the CMP composition is supplied onto the polishing pad, as a result of which a surface of the substrate is polished to a flat surface.

Following CMP, a large amount of particles is generated due to polished debris generated by polishing and abrasive grains from the CMP composition. For removing these foreign substances, cleaning is followed. In the present invention, since the HAp is used as the abrasive grain, the abrasive grain can be removed by being dissolved in an acid. Therefore, it is preferable that the CMP process of the present invention further include a cleaning step including bringing a substrate into contact with an acid to remove the remaining HAp. The acid may be brought into contact with by immersing the substrate in a treatment bath containing the acid, or by spraying the acid on the substrate. A type of acid is preferably an acid that can dissolve the HAp and does not corrode the substrate. The type of acid may be either an inorganic acid or an organic acid. It is preferable to use the organic acid in a form of an aqueous solution, from the viewpoint of its good effect on removing the HAp and facilitation of its handling. Examples of the organic acids include, but are not limited to, citric acid, tartaric acid, malic acid, tricarballylic acid, malonic acid, glycolic acid, glutaric acid, succinic acid, lactic acid, acetic acid, propionic acid, n-butyric acid, and the like, or an arbitrary combination thereof. Among them, citric acid has an excellent ability to dissolve the HAp, and is preferred. A concentration of the organic acid when using the organic acid in the form of an aqueous solution for cleaning is not particularly limited. For example, the aqueous solution of an organic acid having a concentration of approximately 0.1 to 10.0% by mass and preferably approximately 0.5 to 5.0% by mass, can be used. The substrate may be brought into contact with the acid at room temperature, which is not limited thereto. For example, it may be brought into contact with the acid in an environment of approximately 10 to 40° C. or in an environment of approximately 15 to 30° C. After contact with the acid, it is preferable to remove the acid sufficiently by washing it with pure water or the like. Then, drying may be performed by a normal process. Therefore, the CMP process of the present invention may include a step of drying a substrate after the cleaning step.

In the cleaning step, in addition to the contact with the acid, a conventional method used for cleaning after CMP may be combined. Examples of such cleaning methods include, but are not limited to, for, example, SC1 cleaning or SC2 cleaning using a specific cleaning solution; contact-type physical cleaning including buff cleaning and a method in which particles are physically swept away using cleaning members such as a roll brush and pencil brush; non-contact-type physical cleaning such as two-fluid cleaning and ultrasonic cleaning; and pure water cleaning. These cleaning methods may be appropriately combined depending on the type of the substrate and the like.

The present invention will be specifically described below by way of Examples, but the present invention is not limited to these aspects.

### EXAMPLES

### Providing Abrasive Composition for CMP

Four types of slurries were provided as CMP compositions with a concentration of abrasive grains of 5.0% by mass or 10.0% by mass and a pH of 7.0 or 8.0, using deionized water, HAp as an abrasive grain, a dispersant, and potassium hydroxide as a pH adjuster. The average particle size of the abrasive grains in the slurry was approximately 150 nm with respect to all the slurries.

### Polishing of Substrate

30-mm-square TEOS wafers were provided as substrates to be polished. The substrate was set in a CMP apparatus and polished three times at a pressure of 3 psi, a pad rotation speed of 100 rpm, and a wafer rotation speed of 101 rpm for each of the four types of slurries provided above. After polishing, each substrate was rinsed with pure water and blown with nitrogen, and the state of the substrate being polished was observed. As a result, the substrate could be confirmedly polished with respect to all slurries.

### Cleaning Test

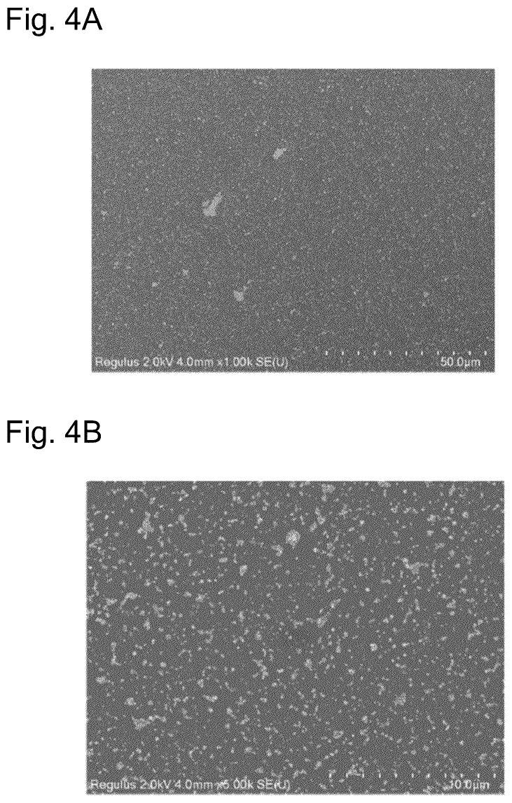

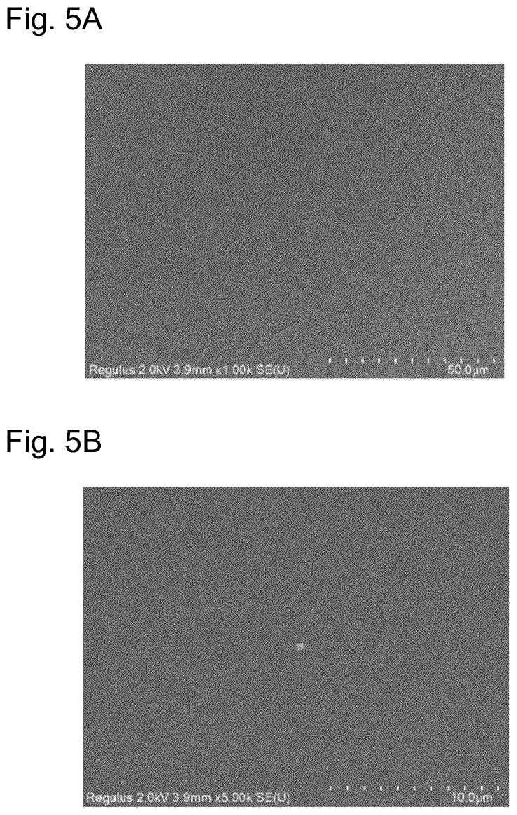

An aqueous solution of citric acid (pH 2.17) with a concentration of 1.0% by mass was provided as a cleaning solution. The substrate after having been polished with the slurry containing 10.0% by mass of HAp and having a pH of 8.0, was immersed in the citric acid solution at room temperature for 10 minutes. Further, a control sample was prepared by immersing the substrate after having been polished with the same slurry in ultrapure water for 10 minutes. After immersion, the substrate was removed with tweezers, washed with pure water, and then dried with nitrogen blow. The substrate after drying was subjected to an elemental analysis of the surface of the substrate by using an X-ray fluorescence analyzer. The results are shown in Table 1. The scanning electron microscope (SEM) images of the surface of the substrate after cleaning are also shown in FIGS. 4A, 4B, 5A, and 5B. FIGS. 4A and 4B are the SEM images (1,000-time magnification and 5,000-time magnification, respectively) of the surface of the substrate after washing with ultrapure water. FIGS. 5A and 5B are the SEM images (1,000-time magnification and 5,000-time magnification, respectively) of the surface of the substrate after cleaning with a citric acid aqueous solution.

TABLE 1
(mass %)

| Component | (1) Ultrapure water | (2) 1 wt % citric acid |
|---|---|---|
| C | 0.619 | 0.495 |
| O | 36.768 | 37.490 |
| Si | 62.542 | 62.016 |
| P | 0.047 | — |
| Ca | 0.025 | — |
| Total | 100 | 100 |

As shown in Table 1, phosphorus and calcium were not detected after cleaning with the aqueous solution of citric acid. The cleaning with the aqueous solution of citric acid was found to enable removal of phosphorus and calcium contained in the HAp. Also, as shown in FIGS. 5A and 5B, the cleaning with the aqueous solution of citric acid was found to enable most of the particles to be removed.

Several embodiments of the present invention have been described above, however, the above-described embodiments of the present invention are for the purpose of facilitating the understanding of the present invention and are not intended to limit the present invention. The present invention may be modified or improved without departing from the gist of the invention, and the present invention includes equivalents thereof. In addition, the elements described in the claims and the specification can be arbitrarily combined or omitted within a range in which the above-mentioned problems are at least partially solved, or within a range in which at least a part of the advantages is achieved.

What is claimed is:

1. A process of chemical mechanical polishing, comprising
providing a chemical mechanical polishing composition comprising
an abrasive grain that is hydroxyapatite,
water, and
a pH adjuster; and
using the chemical mechanical polishing composition to perform chemical mechanical polishing on a substrate.

2. The process according to claim 1, further comprising cleaning the substrate after chemical mechanical polishing,
wherein the cleaning comprises bringing the substrate into contact with an acid to remove the residual hydroxyapatite.

3. The process according to claim 2, wherein the acid is an aqueous solution of an organic acid.

4. The process according to claim 3, wherein the aqueous solution of the organic acid is an aqueous solution of citric acid.

5. The process according to claim 3, wherein the organic acid aqueous solution has a concentration of 0.1 to 10.0% by mass.

6. The process according to claim 2, wherein the substrate is brought into contact with an acid in an environment of 10 to 40° C.

7. The process according to claim 2, further comprising drying the substrate after cleaning.

8. The process according to claim 2, wherein the chemical mechanical polishing composition has a pH of 6.0 to 14.0.

9. The process according to claim 2, wherein the hydroxyapatite has an average particle size of 1 to 1,000 nm.

10. The process according to claim 2, wherein the pH adjuster is at least one selected from potassium hydroxide, calcium hydroxide, ammonia, or an arbitrary combination thereof.

11. The process according to claim 2, wherein the substrate is a semiconductor element.

12. The process according to claim 2, wherein the chemical mechanical polishing composition has zeta potential of −5 mV or less.

13. The process according to claim 2, wherein the chemical mechanical polishing composition further comprises an additive, the additive being at least one selected from a dispersant, a surfactant, a pH stabilizer, a solvent other than water, or an arbitrary combination thereof.

14. The process according to claim 2, wherein the additive has a total concentration of 0.001 to 10.0% by mass based on a mass of the CMP composition.

15. A chemical mechanical polishing composition comprising
an abrasive grain that is hydroxyapatite,
water, and
a pH adjuster.

16. The chemical mechanical polishing composition according to claim 15, wherein the chemical mechanical polishing composition has a pH of 6.0 to 14.0.

17. The chemical mechanical polishing composition according to claim 15, wherein the hydroxyapatite has an average particle size of 1 to 1,000 nm.

18. The chemical mechanical polishing composition according to claim 15, wherein the pH adjuster is at least one selected from potassium hydroxide, calcium hydroxide, ammonia, or combinations thereof.

19. The chemical mechanical polishing composition according to claim 15, wherein the chemical mechanical polishing composition has zeta potential of −5 mV or less.

20. The chemical mechanical polishing composition according to claim 15, further comprising an additive, the additive being at least one selected from a dispersant, a surfactant, a pH stabilizer, a solvent other than water, or an arbitrary combination thereof.
